(19) United States
(12) Patent Application Publication
(10) Pub. No.: US 2014/0246070 A1
(43) Pub. Date: Sep. 4, 2014

(54) THIN FILM SOLAR MODULE HAVING SERIES CONNECTION AND METHOD FOR THE SERIES CONNECTION OF THIN FILM SOLAR CELLS

(71) Applicant: Franz Karg, Muenchen (DE)

(72) Inventor: Franz Karg, Muenchen (DE)

(21) Appl. No.: 14/241,261

(22) PCT Filed: Sep. 14, 2012
(86) PCT No.: PCT/EP2012/068171

§ 371 Date: Feb. 26, 2014

(30) Foreign Application Priority Data
Sep. 19, 2011 (EP) 11181769.8

(51) Int. Cl. H01L 31/05; H01L 31/0224

(52) U.S. Cl. CPC H01L 31/0508; H01L 31/022425
USPC 136/244; 438/80

(57) ABSTRACT

A thin film solar module having a series connection is described. The thin film solar module has a back electrode layer that is divided into regions by a first set of structuring lines, a photoactive semiconductor layer that is arranged on the back electrode layer and divided by a second set of structuring lines, and a front electrode layer that is arranged on the side of the photoactive semiconductor layer opposite the back electrode layer and divided into regions by a third set of structuring lines.

The invention relates to a thin-film solar module with series connection and a method for the series connection of thin-film solar cells to form a thin-film solar module.

Photovoltaic layer systems for the direct conversion of sunlight into electrical energy are well known. The materials and the arrangement of the layers are coordinated such that incident radiation is converted directly into electrical current by one or a plurality of semiconducting layers with the greatest possible radiation yield. Photovoltaic and a really extensive layer systems are referred to as “solar cells”.

Solar cells contain, in all cases, semiconductor material. Solar cells that require carrier substrates to provide adequate mechanical stability are referred to as “thin-film solar cells”. Due to the physical properties and the technological handling quality, thin-film systems with amorphous, micromorphous, or polycrystalline silicon, cadmium telluride (CdTe), gallium arsenide (GaAs), copper-indium-(gallium)-selenide sulfide (Cu(In,Ga)(S,Se)₂), copper-zinc-tin-sulfoselenide (CZTS from the kesterite group) as well as organic semiconductors are particularly suitable for solar cells. The pentenary semiconductor Cu(In,Ga) (S,Se)₂ belongs to the group of the chalcopyrite semiconductors that are frequently referred to as CIS (copper-indium-diselenide or -sulfide) or CIGS (copper-indium-gallium-diselenide, copper-indium-gallium-disulfide, or copper-indium-gallium-disulfoselenide). In the acronym CIGS, S can represent selenium, sulfur, or a mixture of the two chalcogens.

Known carrier substrates for thin-film solar cells contain inorganic glass, polymers, metals, or metal alloys and can, depending on the layer thickness and material properties, be designed as rigid plates or flexible films. Due to the widely available carrier substrates and to simple monolithic series connection, large-area arrangements of thin-film solar cells can be produced economically.

An electrical circuit of a plurality of solar cells is referred to as a photovoltaic module or a solar module. The circuit of solar cells is durably protected against environmental influences in known weather-resistant structures. Customarily, low-iron soda lime glasses and adhesion-promoting polymer films are connected to the solar cells to form a weather-resistant photovoltaic module. The photovoltaic modules can be integrated via connection sockets into a circuit of multiple photovoltaic modules. The circuit of photovoltaic modules is connected via known power electronics to the public supply network or to an autonomous electrical energy supply.

In the series connection of thin-film solar modules, an integrated series connection is usually used. In the integrated series connection, the active cell area is divided into longitudinal strips, each of which represents an individual thin-film solar cell. The individual thin-film solar cells are connected in series on their longitudinal edges with the respective adjacent cells. The back electrode layer, photoactive semiconductor layer, and front electrode layer are divided by structuring lines PR, PA, PF, and the back electrode layer of a first region is connected via a second structuring line PA to the front electrode layer of an adjacent region.

It has been demonstrated in practice that the level of efficiency of an individual thin-film solar cell declines with increasing solar cell width. To limit the losses of the solar module, depending on the cell structure used, the width of an individual solar cell cannot exceed roughly 1 cm with CIS solar modules or 1 cm to 1.5 cm with amorphous silicon solar modules. Thin-film solar modulee with individual solar cells of greater width would be, because of their low voltages and relatively high currents, advantageous for certain applications, for example, for charging batteries.

The object of the present invention consists in providing an improved thin-film solar module with a higher level of efficiency with widened individual thin-film solar cells—equivalent to a reduced number of series-connected individual solar cells per module area.

The object of the present invention is accomplished according to the invention by a thin-film solar module with series connection according to claim 1. Preferred embodiments emerge from the subclaims.

The invention further comprises a method for the series connection of thin-film solar cells to form a thin-film solar module.

A use of the method according to the invention emerges from other claims.

An individual thin-film solar cell consists substantially of three layers: a back electrode layer on the side facing away from the light, a front electrode layer, and a photoactive semiconductor layer therebetween. The flow of current generated by the incidence of light is collected inside a solar cell perpendicular to the three structuring lines PR, PA, PF in the front electrode layer, conducted to the second structuring line PA, and passed on from there downward to the back electrode layer of the adjacent cell.

A fundamental characteristic of this design is the current density inside the front electrode layer sharply increasing in the direction of the series connection, or the decreasing current density in the back electrode layer. In contrast to the back electrode layer, usually made of highly conductive metals, the front electrode layer has lower conductivity by at least a factor of 2, but most often by at least a factor of 10 to 100. This is caused by the requirement for high optical transparency of the front electrode layer, which is possible only with thin, not too heavily doped front electrode layers. Due to the low conductivity of the front electrode layer, significant ohmic losses occur, which increase nonlinearly in the direction transverse to the solar cell. To be sure, the ohmic losses are reduced with a sharp reduction of the solar cell width; however, the losses of active surface increase due to the increasing number of structuring lines PR, PA, PF and the associated photovoltaically inactive fractions of the surfaces. With a given solar module width, the number of individual solar cells and with it the overall voltage of the solar module cannot be varied in wide ranges. The optimal width of the cell wₒₚₜ with given optoelectronic properties of the photoactive semiconductor layer and the front electrode layer is thus fixed within rather narrow limits.

The solution of the problem according to the invention resides in use of the sufficiently available conductivity of the metallic back electrode layer to support the current flow, which normally would have to be undertaken by the front electrode layer. For this purpose, the shape of an individual solar cell is not implemented as an exact rectangle, but, instead, has bulges on one longitudinal edge, in which the current flow is taken over from the weakly conductive front electrode layer by the back electrode layer via the second structuring line PA produced with special shaping. The mean path distances inside the front electrode layer required for current collection can thus be reduced. This yields lower series resistance losses and new degrees of freedom in the design of the electrical characteristics of thin-film solar modules. With given substrate formats, the number of individual solar cells and thus the voltage/current ratio of the solar module can be virtually freely selected. In particular, for applications for battery charging using photovoltaic modules, these are critical prerequisites. However, even with other applications, it is advantageous to use modules with lower voltages and higher currents, for example, in order to be able to configure longer chains of series-connected solar cells inside a large photovoltaic system.

A thin-film solar module according to the invention with series connection on a substrate consequently comprises at least:
a back electrode layer that is divided by structuring lines PR,
a photoactive semiconductor layer that is arranged on the back electrode layer and is divided by structuring lines PA, and
a front electrode layer that is arranged on the side of the photoactive semiconductor layer opposite the back electrode layer, and that is divided by structuring lines PF.

An electrical connection of the front and back electrode of adjacent individual cells is made via the structuring line PA. Moreover, the structuring lines PR are formed with bulges and edges and the second structuring lines PA are formed with bulges and edges relative to each other such that the mean path distance of the current generated in the photoactive semiconductor layer through the front electrode layer is reduced.

In the context of the present invention, “edge” is a section of a structuring line PA, PR, or PF that includes no bulge.

The thin-film solar module according to the invention can be structured in the so-called “substrate configuration” or in the so-called “superstrate configuration”. In both configurations, the structure consists of a plurality of thin, semiconducting, and metallic layers on an insulating plate-shaped material.

An advantageous embodiment of a thin-film solar module according to the invention with series connection and substrate configuration comprises at least:
a back electrode layer that is arranged on a substrate and is divided by structuring lines PR,
a photoactive semiconductor layer that is arranged on the back electrode layer and that is divided by structuring lines PA, and
a front electrode layer that is arranged on the photoactive semiconductor layer, wherein at least the front electrode layer is divided into regions by structuring lines PF and the front electrode layer of a first region is connected in series connection to the back electrode layer of a second region,
   wherein the structuring lines PR are formed with bulges and edges and the structuring lines PA are formed with bulges and edges relative to each other such that the mean path distance of the current generated in the photoactive semiconductor layer through the front electrode layer is reduced.

In a preferred embodiment of the thin-film solar module according to the invention, the front electrode layer and the photoactive semiconductor layer are divided into regions by structuring lines PF.

The substrate is made here, for example, of glass with relatively low light transmission, with the equal possibility of using other electrically insulating materials with desired stability and inert behavior relative to the process steps performed.

The highly conductive back electrode layer contains, for example, a metal such as molybdenum (Mo), aluminum (Al), copper (Cu), or titanium (Ti) and can be applied on the substrate, for example, by vapor deposition or by magnetic field assisted cathode sputtering. The back electrode layer is divided by first structuring lines PR.

A photoactive semiconductor layer that also fills the structuring lines PR is arranged on the back electrode layer. Any layer structure suitable for production of thin-film solar cells is suitable as the photoactive semiconductor layer. Such a layer structure preferably contains amorphous, micromorphous, or polycrystalline silicon with different doping, cadmium telluride (CdTe), gallium arsenide (GaAs), copper-zinc-tin-sulfoselenide (CZTS), organic semiconductors, or copper-indium-(Gallium)-selenide-sulfide (Cu(In,Ga)(S,Se)₂). The photoactive semiconductor layer is divided at least by the structuring lines PA, but can also be divided by the structuring lines PF.

Arranged on the photoactive semiconductor layer is at least one front electrode layer that is largely transparent to radiation in the range of the spectral sensitivity of the solar cell such that the incident sunlight is only slightly weakened. The front electrode layer also fills the structuring lines PA in the photoactive semiconductor layer, by which means the front electrode layer of a first region is connected in series connection to the back electrode layer of a second region.

The front electrode layer preferably contains a transparent, conductive metal oxide layer, in particular zinc oxide (ZnO), aluminum-doped zinc oxide (ZnO:Al), boron-doped zinc oxide (ZnO:B), indium-doped zinc oxide (ZnO:In), gallium-doped zinc oxide (ZnO:Ga), fluorine-doped tin oxide (SnO₂:F), antimony-doped tin oxide (SnO₂:Sb), or indium tin oxide (ITO). The front electrode layer can be applied to the photoactive semiconductor layer, for example, by vapor deposition, chemical gas phase deposition (CVD) or by magnetic field assisted cathode sputtering below. Before the deposition of the front electrode, a thin buffer layer (e.g., made of II-VI or III-V semiconductors) can also additionally be applied to improve the optoelectronic properties.

In the case of the substrate configuration, the front electrode layer and, optionally, also the photoactive semiconductor layer are divided by structuring lines PF, by which means the individual thin-film solar cells of the thin-film solar module are series connected to each other.

An advantageous embodiment of a thin-film solar module according to the invention with series connection in superstrate configuration comprises at least:
a front electrode layer that is arranged on a transparent substrate and that is divided by structuring lines PF,
a photoactive semiconductor layer that is arranged on the front electrode layer and that is divided by structuring lines PA, and
a back electrode layer that is arranged on the photoactive semiconductor layer, wherein at least the back electrode layer is divided into regions by structuring lines PR and the back electrode layer of a first region is connected in series connection to the front electrode layer of a second region,
   wherein the structuring lines PR are formed with bulges and edges and the structuring lines PA are formed with bulges and edges relative to each other such that the mean path distance of the current generated in the photoactive semiconductor layer through the front electrode layer is reduced.

The embodiment in the superstrate configuration is realized by a layer structure on the surface of a transparent substrate facing away from the light. The transparent substrate is made, for example, of extra white glass with low iron content, with the equal possibility of using other electrically insulating and optically transparent materials with desired stability and inert behavior relative to the process steps performed.

In this embodiment of the thin-film solar module according to the invention, the front electrode layer is divided by structuring lines PF, the photoactive semiconductor layer is divided by second structuring lines PA and at least the back electrode layer, optionally also the adjacent absorber layer, is/are divided by third structuring lines PR. The series connection of the individual thin-film solar cells occurs in this case through the connection of the back electrode layer of a first region to the front electrode layer of a second region.

In the thin-film solar module according to the invention, the structuring lines PR are formed with bulges and edges and the structuring lines PA are formed with bulges and edges relative to each other such that the mean path distance of the current generated in the photoactive semiconductor layer through the front electrode layer is reduced.

The current generated in the photoactive semiconductor layer is picked up by the front electrode and is passed on via the second structuring line PA to the back electrode layer of the next thin-film solar cell in series connection. The bulges of the second structuring line PA result in the fact that the current no longer flows through the front electrode layer in straight paths parallel to the longitudinal or series connection direction of the thin-film solar cell, but, instead, follows the path of the least electrical resistance. By means of the bulges of the second structuring line PA, the mean distance of various regions of the front electrode layer to the second structuring line PA is reduced. Thus, the mean path distance of the current generated in the photovoltaic semiconductor layer through the front electrode layer is reduced and the mean electrical resistance through the front electrode layer is reduced. The electrical current is guided via the structuring line PA into the better electrically conductive back electrode layer. This results in a lower total resistance of the thin-film solar cell.

In an advantageous embodiment of the thin-film solar module according to the invention, the structuring lines PF are also formed with analogous bulges and edges. By means of this measure, the photovoltaically active area of each individual thin-film solar cell can be enlarged since the photovoltaically inactive area between second structuring line PA and the adjacent third structuring line PR is reduced.

In another advantageous embodiment of the thin-film solar module according to the invention, the bulges of the structuring line PR, of the structuring lines PA and PR, or of the structuring line PR, PA, and PF are formed tapering to a point.

In another advantageous embodiment of the thin-film solar module according to the invention, the bulges of at least the structuring lines PR, optionally, also the structuring lines PA and/or PF are formed as triangles.

In another advantageous embodiment of the thin-film solar module according to the invention, the bulges of the structuring lines PA are formed linearly or rectangularly. This embodiment of the structuring lines PA is technically particularly simple to execute.

In another advantageous embodiment of the thin-film solar module according to the invention, the bulges of adjacent structuring lines PR, PA, and PF are formed at least approx. parallel to each other. By this means, the photovoltaically inactive area between the structuring lines PF, PA, and PR is reduced and the photovoltaically active area of each individual thin-film solar cell is enlarged. Here, the bulges of the structuring lines PR, PA and, optionally, PF are aimed in the same direction (e.g., perpendicular to the lengthwise direction of the structuring lines), i.e., the structuring lines are in each case bulged in the same direction (e.g., perpendicular to their lengthwise direction). Thus, the structuring lines PR, PA and, optionally, PF are provided with aligned bulges.

The mean path distance of the current generated in the photoactive semiconductor layer through the front electrode layer, hereinafter also referred to as “photocurrent”, is preferably less than or equal to the optimal cell width wₒₚₜ.

As already described in the introduction, it has been demonstrated in practice that the level of efficiency of an individual thin-film solar cell drops with the increasing width of the solar cell. This is, among other things, the result of the ohmic resistance which increases with the cell width, resulting primarily from the limited conductivity of the transparent front electrode. Inversely, with decreasing cell width, the relative fraction of the optoelectronically inactive area that is required for the structuring lines increases. In conventional series connection, the optimal cell width wₒₚₜ resulting from these two contrary effects depends substantially on the voltage and the photocurrent density of a respective solar cell. As experiments have demonstrated, the optimal cell width wₒₚₜ in a CIS- or CIGS-thin-film solar module with an open current voltage of ca. 0.5 V and comparatively high photocurrent densities is, for instance, from 5 mm to 10 mm and preferably from 4.5 mm to 6.5 mm. In the case of solar cells with high open current voltages and comparatively low photocurrent densities, such as, for example, amorphous silicon solar cells with an open current voltage of ca. 0.9 V, the optimal cell width wₒₚₜ is, for example, from 7 mm to 15 mm and preferably from 7.5 mm to 10.5 mm.

In another advantageous embodiment of the thin-film solar module according to the invention, the bulges of the structuring line PR are formed at a minimum distance d from the structuring line PF of the adjacent cell less than or equal to the optimal cell width wₒₚₜ. The structuring line PF relevant for the distance d is situated on the side turned away from the nearest structuring line PA (see, for example, FIG. 4 for clarification). The relevant structuring line PF delimits the front electrode layer of the previous thin-film solar cell in series connection.

In an advantageous embodiment of the thin-film solar module according to the invention, the bulges are formed at a distance a along the structuring lines, with the distance a less than or equal to twice the distance of wₒₚₜ. This has the particular advantage that the photocurrent generated between the two bulges must travel a path that is smaller than or equal to the optimal cell width wₒₚₜ in order to arrive via the structuring line PA to the back electrode.

In another advantageous embodiment of the thin-film solar module according to the invention, the back electrode layer has an electrical sheet resistance lower by at least a factor of 10, preferably a factor of 100 than the front electrode layer. By this means is possible to reduce the base width bp_{PR} of the bulges of the structuring line PR of the back electrode. A reduction of the base width bp_{PR} results in a reduction of the photoelectrically inactive area and thus results in an increase in the level of efficiency.

A further aspect of the invention comprises a method for producing and for series connecting a thin-film solar module in a so-called substrate configuration, wherein:
a) a back electrode layer is deposited on a substrate and the back electrode layer is divided by first structuring lines PR,
b) a photoactive semiconductor layer is deposited on the back electrode layer and the photoactive semiconductor layer is divided by second structuring lines PA,
c) a front electrode layer is deposited on the photoactive semiconductor layer, the front electrode layer and the photoactive semiconductor layer are divided into regions by third structuring lines PF, and the front electrode layer of a first region is connected in series connection to the back electrode layer of a second region,
   wherein the first structuring line PR is formed with bulges and edges and the second structuring line PA is formed with bulges and edges relative to each other such that the mean path distance of the current generated in the photoactive semiconductor layer through the front electrode layer is reduced.

A further aspect of the invention comprises a method according to the invention for producing and for series connecting a thin-film solar module in a so-called superstrate configuration, wherein
a) a front electrode layer is deposited on a transparent substrate and the front electrode layer is divided by first structuring lines PF,
b) a photoactive semiconductor layer is deposited on the front electrode layer, and the photoactive semiconductor layer is divided by second structuring lines PA,
c) a back electrode layer is deposited on the photoactive semiconductor layer, the back electrode layer and the photoactive semiconductor layer are divided into regions by third structuring lines PR, and the back electrode layer of a first region is connected in series connection to the front electrode layer of a second region,
   wherein the structuring lines PR are formed with bulges and edges and the structuring lines PA are formed with bulges and edges relative to each other such that the mean path distance of the current generated in the photoactive semiconductor layer through the front electrode layer is reduced.

A further aspect of the invention comprises the use of the method according to the invention for producing and series connecting a thin-film solar module, in particular a thin-film solar module made of amorphous, micromorphous, or polycrystalline silicon, cadmium telluride (CdTe), gallium arsenide (GaAs), kesterite-based semiconductors such as copper-zinc-tin-sulfoselenide (CZTS), chalcopyrite-based semiconductors such as copper-indium-(gallium)-selenide-sulfide (Cu(In,Ga)(S,Se)₂), or organic semiconductors.

### BRIEF DESCRIPTION OF THE DRAWINGS

The invention is explained in detail in the following with reference to figures and an example. The figures are not completely true to scale. The invention is in no way restricted by the figures. They depict:

FIG. 1 a schematic cross-sectional representation of an exemplary embodiment of the thin-film solar module according to the invention with two series-connected thin-film solar cells,

FIG. 2 a cross-sectional representation along section line A-A′ of FIG. 1,

FIG. 3 a schematic representation of the current flow through two series-connected thin-film solar cells,

FIG. 4 a schematic representation of the sequence of the structuring lines PR, PA, and PF of a thin-film solar module according to the invention,

FIG. 5 a schematic representation of an alternative embodiment of the structuring lines PR, PA, and PF of a thin-film solar module according to the invention,

FIG. 6 a schematic representation of an alternative embodiment of the structuring lines PR, PA, and PF of a thin-film solar module according to the invention,

FIG. 7 a schematic representation of an alternative embodiment of the structuring lines PR, PA, and PF of a thin-film solar module according to the invention,

FIG. 8 a schematic representation of an alternative embodiment of the structuring lines PR, PA, and PF of a thin-film solar module according to the invention,

FIG. 9 a schematic cross-sectional representation of an alternative exemplary embodiment (superstrate structure) of a thin-film solar module according to the invention,

FIG. 10 a schematic representation of the sequence of the structuring lines PR, PA, and PF of a thin-film solar module according to the invention (superstrate structure),

FIG. 11 a detailed flowchart of the method according to the invention, and

FIG. 12 a detailed flowchart of an alternative embodiment of the method according to the invention.

### DETAILED DESCRIPTION OF THE DRAWINGS

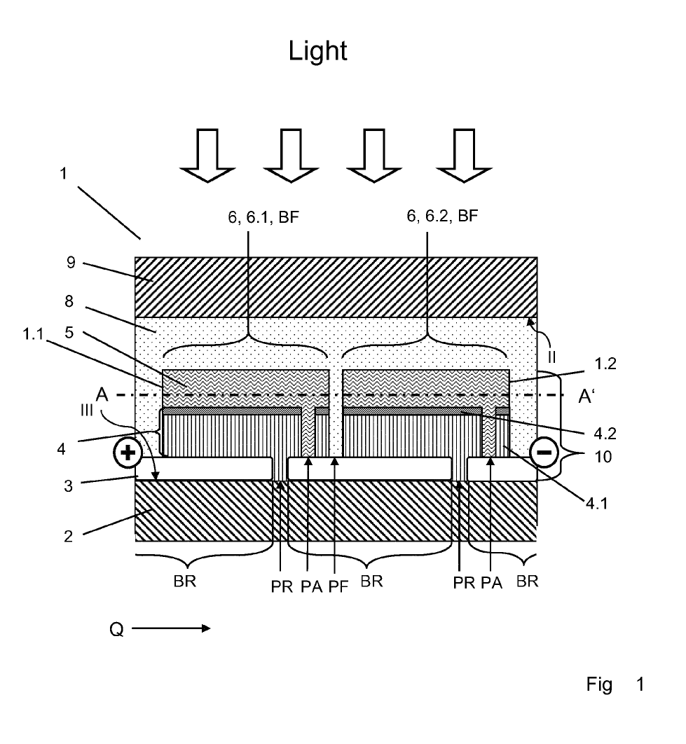

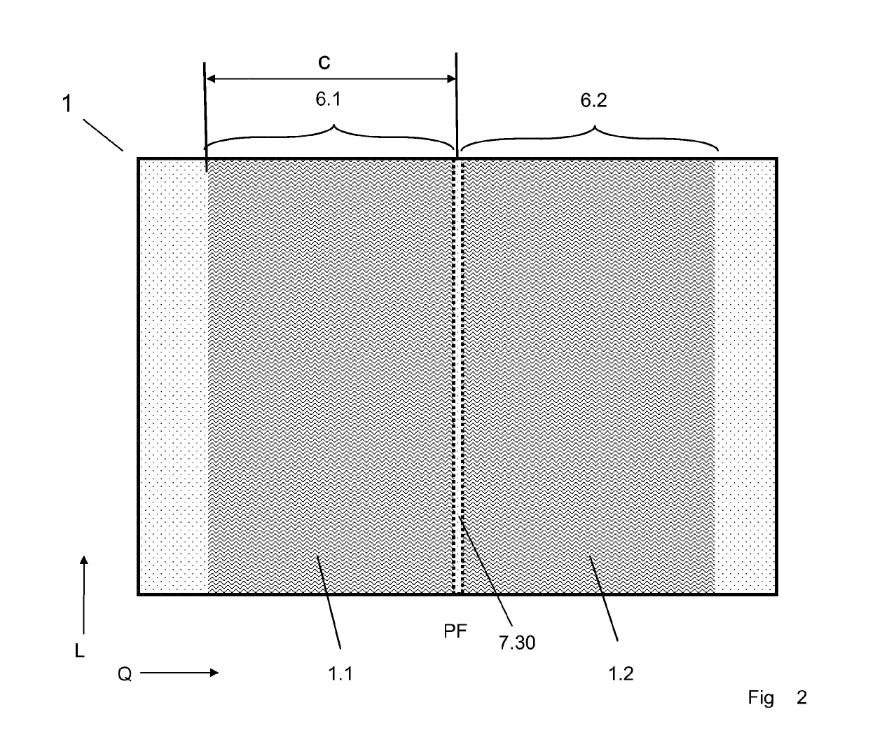

FIG. 1 illustrates a thin-film solar module referred to as a whole by the reference character 1. The thin-film solar module 1 comprises, in an integrated form, a plurality of series-connected solar cells 1.1, 1.2, of which two are depicted in the FIG. 1. FIG. 2 depicts a cross-sectional representation along the section line A-A′ of FIG. 1. The direction L indicates the lengthwise direction or the direction parallel to the structuring lines; the direction Q indicates the transverse direction perpendicular to the structuring lines of the thin-film solar module 1.

The thin-film solar module 1 has a structure corresponding to the so-called substrate configuration. In other words, it has an electrically insulating substrate 2 with a layer structure 10 made of thin layers applied thereupon. The layer structure 10 is arranged on the light-entry-side surface III of the substrate 2. Here, the substrate 2 is made, for example, of glass which can (but need not) have relatively low light transmission.

The layer structure 10 comprises a back electrode layer 3 arranged on the surface III of the substrate 2. The back electrode layer 3 is divided by structuring lines PR. The back electrode layer 3 contains, for example, an opaque metal such as molybdenum (Mo) and can be applied on the substrate 2, for example, by vapor deposition or by magnetic field assisted cathode sputtering. The back electrode layer 3 has a layer thickness from 100 nm to 600 nm, which is, for example, 500 nm. The back electrode layer 3 has an electrical sheet resistance of 1 ohm/square to 0.01 ohm/square, and, for example, of 0.1 ohm/square.

On the back electrode layer 3, a photoactive semiconductor layer 4 is deposited. The photoactive semiconductor layer 4 is divided by structuring lines PA. The photoactive semiconductor layer 4 contains, for example, a doped semiconductor, whose band gap is preferably capable of absorbing the greatest possible fraction of the sunlight. The photoactive semiconductor layer 4 comprises, for example, an absorber layer 4.1 and a buffer layer 4.2. The absorber layer 4.1 contains, for example, a p-conducting chalcopyrite semiconductor, for example, a compound of the group Cu(In,Ga)(S,Se)₂. The absorber layer 4.1 has, for example, a layer thickness of 0.5 μm to 5 μm and, for example, of roughly 2 μm.

A buffer layer 4.2, made in this case, for example, from a single layer of cadmium sulfide (CdS) and a single layer of intrinsic zinc oxide (i-ZnO) (not shown in detail in FIG. 1).

A front electrode layer 5 is applied, for example, by sputtering, on the buffer layer 4.2. The front electrode layer 5 also fills the structuring lines PA, by means of which an electrical line connection is formed between the front electrode layer 5 of a first region 6.1 and the back electrode layer 3 of a second region 6.2. The front electrode layer 5 is transparent to radiation in the visible spectral range (“window electrode”) such that the incident sunlight is only slightly weakened. The transparent front electrode layer 5 is based, for example, on a doped metal oxide, for example, an n-conducting aluminum (Al)-doped zinc oxide (ZnO:Al). Such a front electrode layer 5 is referred to generally as a TCO-layer (TCO=transparent conductive oxide). A heterojunction (i.e., a sequence of layers of opposing conducting types) is formed by the front electrode layer 5 along with the buffer layer 4.2 and the absorber layer 4.1. The buffer layer 4.2 can effect an electronic adaptation between the semiconducting material of the absorber layer 4.1 and the material of the front electrode layer 5. The front electrode layer 5 has a layer thickness of 100 nm to 2000 nm, which is, for example, 1000 nm. The front electrode layer 5 has a sheet resistance of 5 ohm/square to 20 ohm/square and, for example, of 10 ohm/square. The front electrode layer 5 and the photoactive semiconductor layer 4 are divided into individual thin-film solar cells 1.1, 1.2 by structuring lines PF.

For protection against environmental influences, an adhesive layer 8, made, for example, of a polymer, and serving to encapsulate the layer structure 10, is applied on the front electrode layer 5. The light-entry-side surface III of the substrate 2 and the light-exit-side surface II of a transparent substrate 9 are fixedly bonded to each other by the adhesive layer 8. Here, the adhesive layer 8 is, for example, a thermoplastic adhesive layer that becomes deformable through heating and, upon cooling, fixedly bonds the substrate 2 and the transparent substrate 9 to each other. Adhesive layers 8 suitable for the encapsulation are, for example, polyvinyl butyral (PVB) films or ethylene vinyl acetate (EVA) films. The polyvinyl butyral (PVB) or ethylene vinyl acetate (EVA) films have, for example, a thickness of 1 mm.

The transparent substrate 9 is made, for example, of extra white glass with low iron content, with the equal possibility of using other electrically insulating materials with desired stability and inert behavior relative to the process steps performed.

Although not depicted in detail in FIG. 1 and FIG. 2, a peripheral edge gap between the substrate 2 and the transparent substrate 9 is sealed with a sealant serving as a barrier to water. The sealing improves the long-term stability of the thin-film solar module 1 by inhibiting the entry of water and reduces the corrosion of the various layers of the layer structure 10. A suitable sealant is, for example, polyisobutylene (PIB).

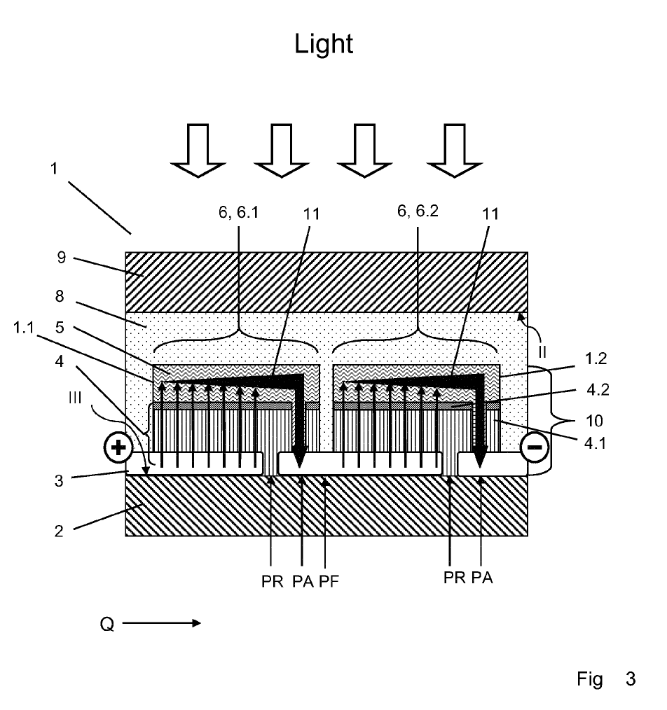

FIG. 3 schematically depicts the current flow through two series-connected thin-film solar cells 1.1, 1.2. The electrical current generated in the photoactive semiconductor layer 4 is collected in the front electrode layer 5 of a first region 6.1 and conducted along the current path 11 to the structuring line PA. The electrical current is conducted to the back electrode layer 2 of a second region 6.2 via the structuring line PA.

In the example presented here, both the resultant positive (+) and the resultant negative voltage connection (−) of the thin-film solar module 1 are guided via the back electrode layer 3 and electrically contacted there. A thin-film solar module 1 according to the invention contains, for example, ca. 100 series-connected thin-film solar cells 1.1, 1.2 and has an open current voltage of ca. 50 V. The width c of an individual thin-film solar cell is from 3 mm to 20 mm and, for example, 10 mm.

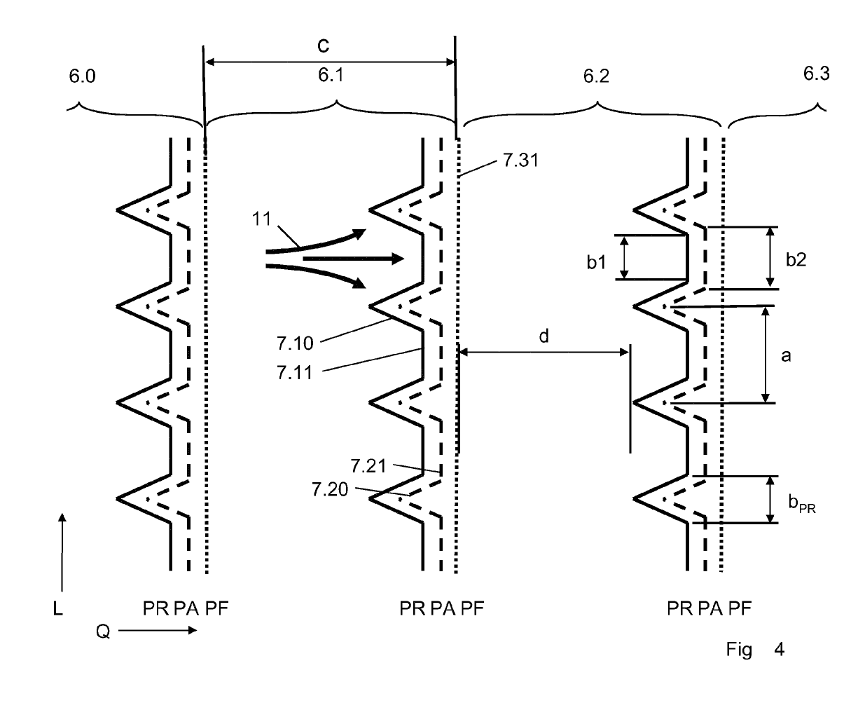

FIG. 4 schematically depicts the sequence of the structuring lines PR, PA, and PF of four series-connected regions 6.0, 6.1, 6.2, and 6.3. The distance between adjacent structuring lines PR as well as the distance between adjacent structuring lines PA corresponds to the width c of the individual thin-film solar cells 1.1, 1.2.

The structuring lines PR have bulges 7.10 and the structuring lines PA have bulges 7.20. The adjacent structuring lines PR and PA are formed near each other approx. parallel or have a parallel course. The bulges 7.10 of the structuring lines PR and the bulges 7.20 of the structuring lines PA have, in each case, a distance a between them of, for example, 12 mm. The distance a corresponds to roughly twice the optimal cell width wₒₚₜ of 6 mm. Between the bulges 7.10, the structuring lines PR run in the lengthwise direction L along the edges 7.11. The base width b_{PR} of the bulges 7.10 is, for example, 2 mm. The length b1 of the edge 7.11 is, for example, 10 mm. The length b2 of the edges 7.20 of the structuring lines PA is, for example, 11 mm. The minimum distance d of a bulge 7.10 of a structuring line PR to the adjacent structuring line PF lying upstream in the direction of the series connection L corresponds to the optimal cell width wₒₚₜ and is, for example, 6 mm. The structuring lines PF are implemented in this exemplary embodiment without bulges and have only one continuous edge 7.31. The bulges 7.10, 7.20 are bulged in each case perpendicular (relative to direction Q) to the lengthwise direction (direction L) of the structuring lines PA, PR.

The current paths of the current generated in the photoactive semiconductor layer 4 through the front electrode layer 5 are identified by arrows with the reference character 11. The current paths 11 run along the paths with the lowest resistance, by which means the mean path distance of the current through the front electrode layer 5 is reduced compared to series-connected solar cells according to the prior art. A transfer of the current transport from the high-ohmic front electrode layer 5 to the low-ohmic back electrode layer 3 results in lower total resistance of the thin-film solar cell.

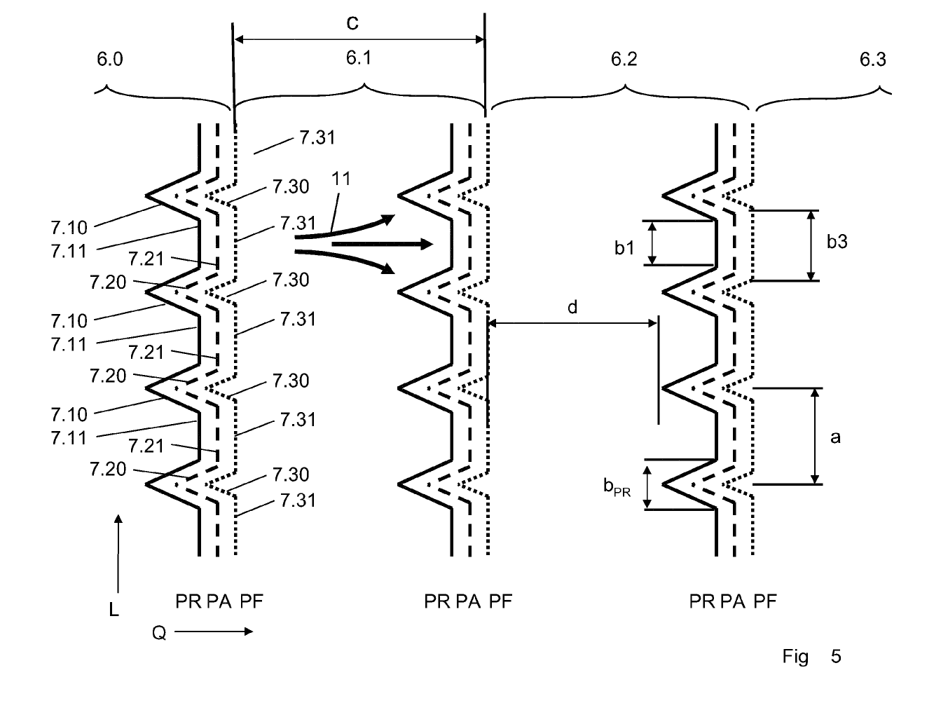

FIG. 5 schematically depicts an alternative embodiment of the structuring lines PR, PA, and PF of four series-connected regions 6.0, 6.1, 6.2, and 6.3. The structuring lines PF are formed with bulges 7.30 and edges 7.31. The adjacent structuring lines PR, PA, and PF are formed approx. parallel to each other or have a parallel course. The bulges 7.10, 7.20, and 7.30 are bulged in each case perpendicular (relative to direction Q) to the lengthwise direction (direction L) of the structuring lines PA, PR, and PF, respectively.

The length b3 of the edges 7.31 is, for example, 11 mm. By this means, the photovoltaically inactive area between structuring line PA and the adjacent structuring line PF is minimized and the photovoltaically active area of each individual thin-film solar cell 1.1, 1.2, 1.3 is enlarged.

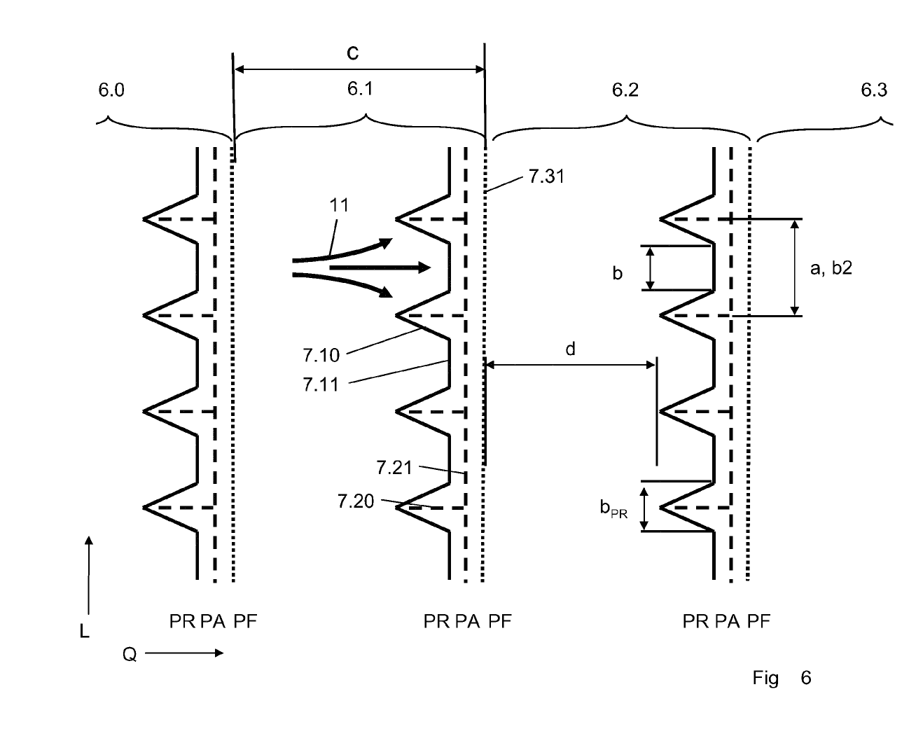

FIG. 6 schematically depicts another alternative embodiment of the structuring lines PR, PA, and PF of a thin-film solar module according to the invention 1. The bulges 7.20 of the structuring lines PA are designed linearly in this exemplary embodiment. The length b2 of the edges 7.21 corresponds in this example to the distance a between the bulges 7.20.

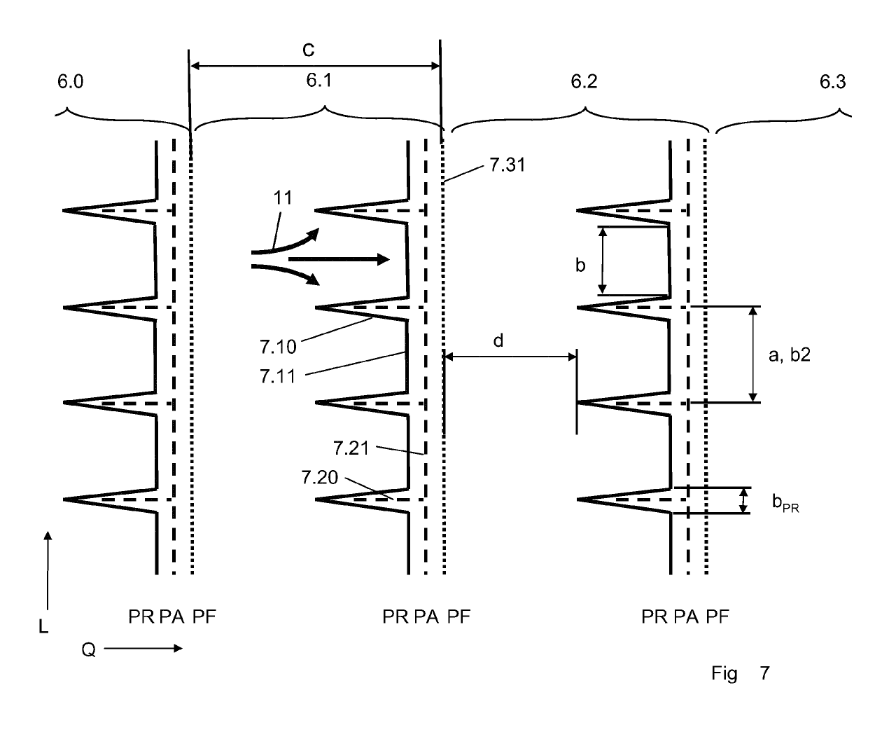

FIG. 7 depicts a variant of the exemplary embodiment of FIG. 6. The distance d between the structuring line PR and of the structuring line PF of two adjacent regions is reduced compared to FIG. 6, with, at the same time, the length b1 of the edge 7.11 increased and the base width b_{PR} reduced.

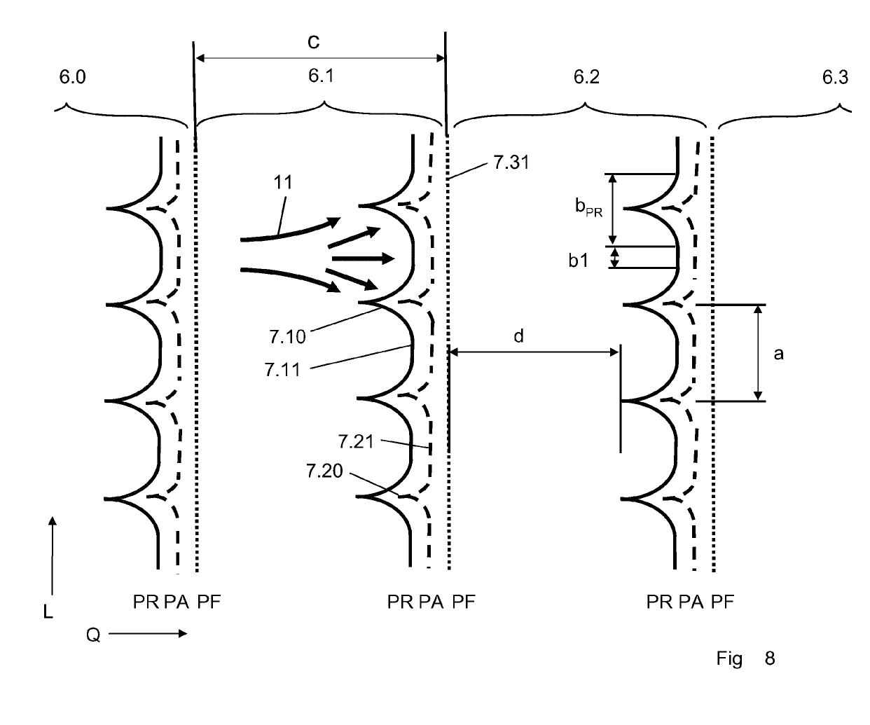

FIG. 8 schematically depicts another alternative embodiment of the structuring lines PR, PA, and PF of a thin-film solar module according to the invention 1. The bulges 7.10 of the structuring lines PR and the bulges 7.20 of the structuring lines PA are formed rounded and tapering to a point. The length b1 of the edge 7.11 of the structuring line PR and the length b2 of the edge 7.21 of the structuring line PA can, in the limiting case, even be 0, such that the structuring lines PR and PA consist of only rounded bulges 7.10, 7.20. The rounded shape of the bulges 7.20 enables a particularly effective shortening of the mean path distance of the current paths 11 in the front electrode layer 5.

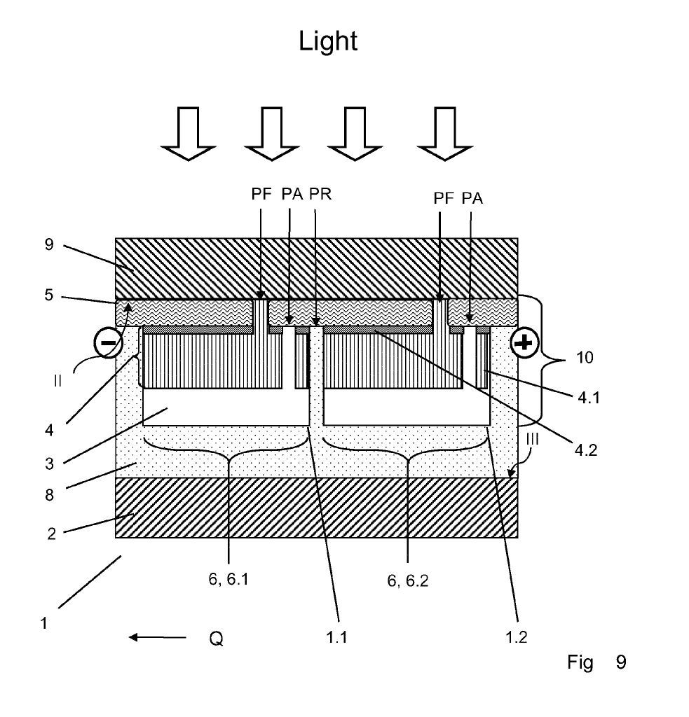

FIG. 9 schematically depicts a cross-section of an alternative exemplary embodiment of the thin-film solar module according to the invention 1 with two series-connected thin-film solar cells 1.1, 1.2. The thin-film solar module 1 has a structure corresponding to the so-called “superstrate configuration”, in other words, it has a transparent substrate 9 with a layer structure 10 made of thin layers applied thereupon. The layer structure 10 comprises a front electrode layer 5 arranged on the light-exit-side surface II of the substrate 9 and divided by structuring lines PF. A photoactive semiconductor layer 4 is deposited on the front electrode layer 5. The photoactive semiconductor layer 4 is divided by structuring lines PA. A back electrode layer 3 that also fills the structuring lines PA is arranged on the photoactive semiconductor layer 4. The back electrode layer 3 and the photoactive semiconductor layer 4 are divided into individual thin-film solar cells 1.1, 1.2 by structuring lines PR. The series connecting of the individual thin-film solar cells 1.1, 1.2 is done by means of structuring lines PA, which electrically conductively connect the back electrode layer 3 of a first region 6.1 to the front electrode layer 5 of a second region 6.1. The materials and material parameters of the substrate 2, 9 and of the layer structure 10 correspond to the exemplary embodiment of a thin-film solar module according to the invention 1 in substrate configuration in FIG. 1. The absorber layer 4.1 contains, for example, a p-conducting absorber such as cadmium telluride (CdTe).

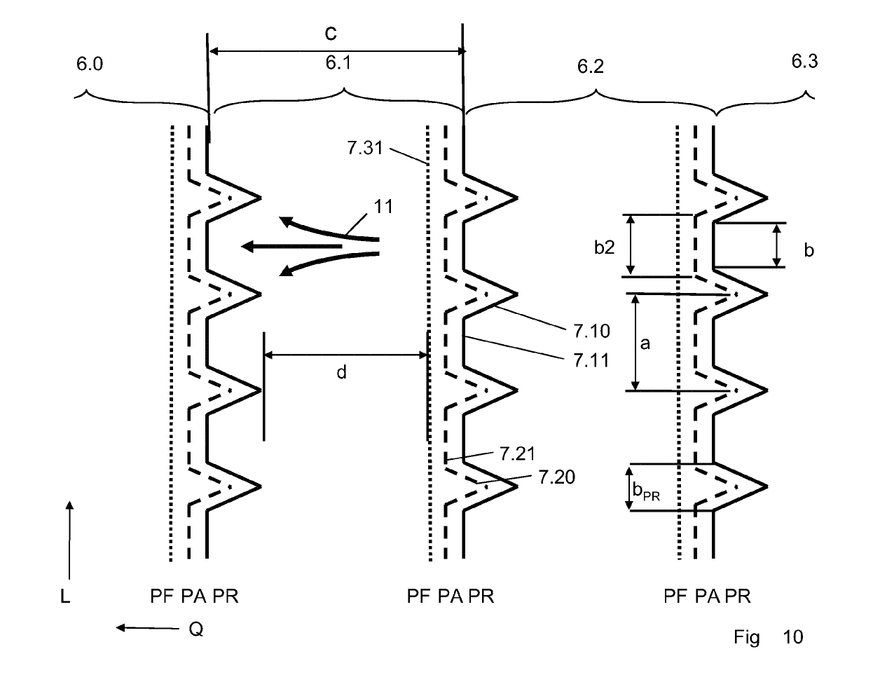

FIG. 10 schematically depicts the sequence of the structuring lines PR, PA, and PF of a thin-film solar module according to the invention in superstrate configuration, as depicted, by way of example, in FIG. 9.

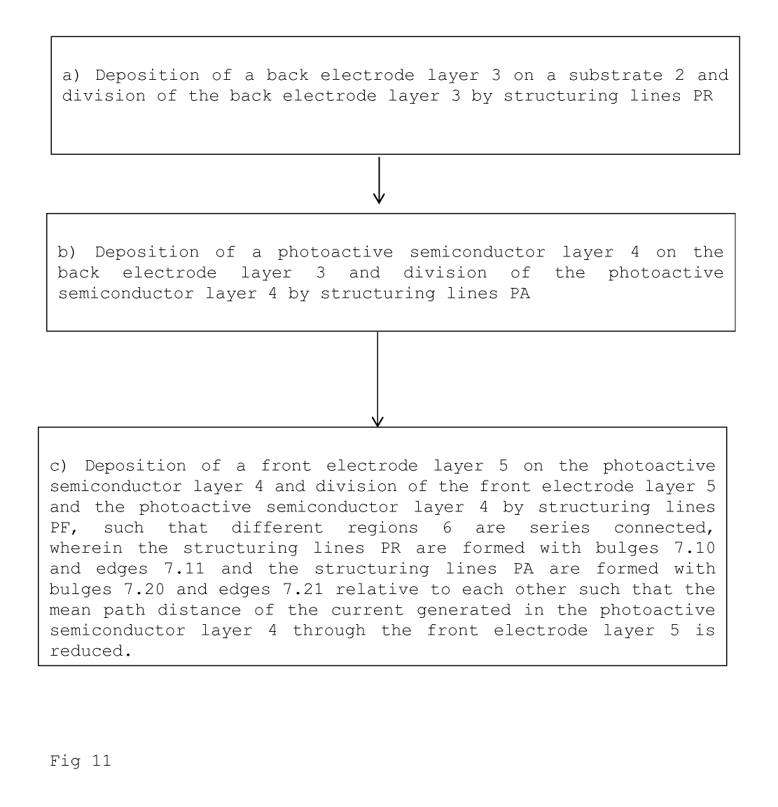

FIG. 11 presents a detailed flowchart of the method according to the invention for producing and series connecting a thin-film solar module according to the invention 1 in substrate configuration. In a first step a), a back electrode layer 3 is deposited on a substrate 2 and the back electrode layer 3 is divided by structuring lines PR. In a second step b), a photoactive semiconductor layer 4 is deposited on the back electrode layer 3 and the photoactive semiconductor layer 4 is divided by structuring lines PA. In a third step c), a front electrode layer 5 is deposited on the photoactive semiconductor layer 4, the front electrode layer 5 and the photoactive semiconductor layer 4 are divided into regions 6 by structuring lines PF, and the front electrode layer 5 of a first region 6 is connected in series connection to the back electrode layer 3 of a second region 6. The structuring lines PR are formed with bulges 7.10 and edges 7.11 and the structuring lines PA with bulges 7.20 and edges 7.21 are formed relative to each other such that the mean path distance of the current generated in the photoactive semiconductor layer 4 through the front electrode layer 5 is reduced.

The incisions for the structuring lines PR, PA, and PF are formed using a suitable structuring technology, such as laser writing, for example, with an Nd:YAG-laser, or machining, for example, by drossing or scratching.

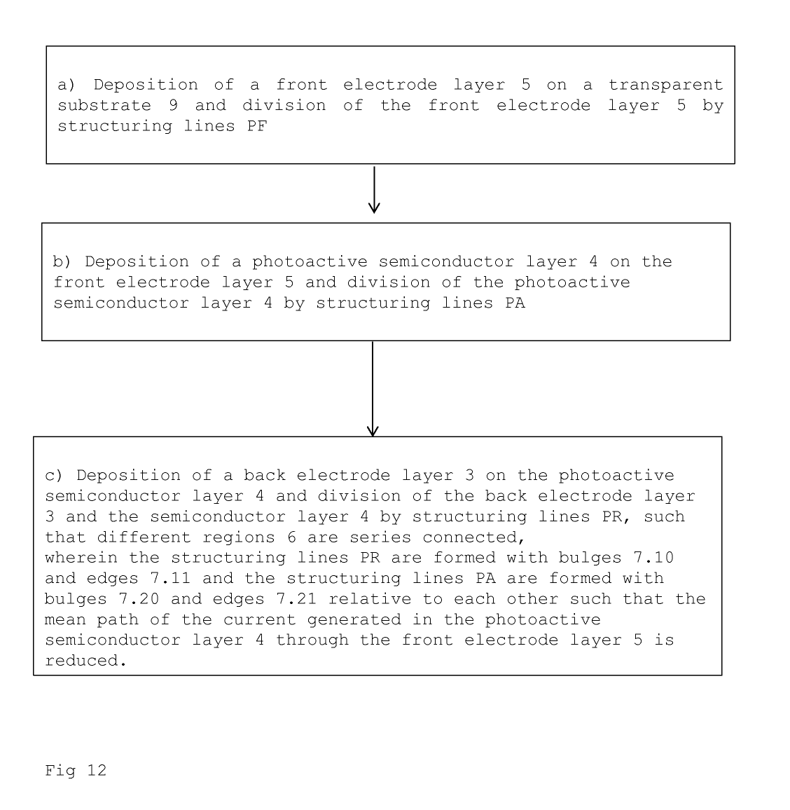

FIG. 12 presents a detailed flowchart of an alternative embodiment of the method according to the invention for producing and series connecting a thin-film solar module according to the invention 1 in superstrate configuration. In a first step a), a front electrode layer 5 is deposited on a transparent substrate 9 and the front electrode layer 5 is divided by structuring lines PF. In a second step b), a photoactive semiconductor layer 4 is deposited on the front electrode layer 5 and the photoactive semiconductor layer 4 is divided by structuring lines PA. In a third step c), a back electrode layer 3 is deposited on the photoactive semiconductor layer 4, the back electrode layer 3 and the photoactive semiconductor layer 4 are divided into regions 6 by structuring lines PR, and the back electrode layer 3 of a first region 6 is connected in series connection to the front electrode layer 5 of a second region 6. The structuring lines PR with bulges 7.10 and edges 7.11 and the structuring lines PA with bulges 7.20 and edges 7.21 are formed relative to each other such that the mean path distance of the current generated in the photoactive semiconductor layer 4 through the front electrode layer 5 is reduced.

### LIST OF REFERENCE CHARACTERS

1 thin-film solar module
1.1, 1.2, 1.3 thin-film solar cells
2 substrate
3 back electrode layer
4 photoactive semiconductor layer
4.1 absorber layer
4.2 buffer layer
5 front electrode layer
6, 6.0, 6.1, 6.2, 6.3 region
7.10, 7.20, 7.30 bulge
7.11, 7.21, 7.31 edge
8 adhesive layer
9 transparent substrate
10 layer structure
11 current flow, current path
a distance between the bulges 7.10, 7.20, 7.30
b1 length of the edge 7.11
b2 length of the edge 7.21
b3 length of the edge 7.31
BF region of the front electrode layer 5
b_{PR} base width of the bulges 7.10
BR region of the back electrode layer 3
c width of a thin-film solar cell 1.1, 1.2, 1.3
d distance
wₒₚₜ optimal cell width
PR structuring line PR
PA structuring line PA
PF structuring line PF
II light-exit-side surface of the transparent substrate 9
III light-entry-side surface of the substrate 2
Q transverse direction
L lengthwise direction, direction of the series connection
A-A′ section line

1. A thin-film solar module with series connection, comprising:
a back electrode layer that is divided into regions BR by structuring lines PR,
a photoactive semiconductor layer that is arranged on the back electrode layer and is divided by structuring lines PA, and
a front electrode layer that is arranged on a side of the photoactive semiconductor layer opposite the back electrode layer and is divided into regions BF by structuring lines PF,
wherein:
regions BF of the front electrode layer are electrically connected to adjacent regions BR of the back electrode layer in series connection by means of structuring lines PA,
the structuring lines PR are formed with bulges and edges, and
the structuring lines PA are formed with bulges and edges relative to each other such that ohmic loss is reduced due to a reduced mean path distance of a current generated in the photoactive semiconductor layer through the front electrode layer.

2. The thin-film solar module according to claim 1, wherein the structuring lines PF are formed with bulges and edges.

3. The thin-film solar module according to claim 1, wherein the bulges of the structuring line PR, of the structuring line PR and PA, or of the structuring line PR, PA and PF are formed tapering to a point.

4. The thin-film solar module according to claim 1, wherein the bulges of at least one of the structuring lines PR, PA or PF are formed triangular.

5. The thin-film solar module according to claim 1, wherein the bulges of the structuring line PA are formed linear or rectangular.

6. The thin-film solar module according to claim 1, wherein the bulges adjacent structuring lines PR, PA, and PF are formed at least approximately parallel to each other.

7. The thin-film solar module according to claim 1, wherein the back electrode layer has a lower electrical sheet resistance, preferably an electrical sheet resistance lower by a factor of 10 and particularly preferably an electrical sheet resistance lower by a factor of 100, than the front electrode layer.

8. The thin-film solar module according to claim 1, wherein the minimum distance d of the bulges of the structuring line PR from the structuring line PF of an adjacent region is smaller than or equal to the optimal cell width (wₒₚₜ) of 5 mm to 15 mm.

9. The thin-film solar module according to claim 8, wherein the distance a between the bulges of the structuring line PR is smaller than or equal to the optimal cell width (wₒₚₜ) of 5 mm to 15 mm.

10. The thin-film solar module according to claim 1, wherein the back electrode layer contains a metal, in particular molybdenum (Mo), aluminum (Al), copper (Cu), titanium (Ti), and/or the front electrode layer (5) contains a transparent, conductive metal oxide layer, in particular zinc oxide (ZnO), aluminum-doped zinc oxide (ZnO:Al), boron-doped zinc oxide (ZnO:B), indium-doped zinc oxide (ZnO:In), gallium-doped zinc oxide (ZnO:Ga), fluorine-doped tin oxide (SnO₂:F), antimony-doped tin oxide (SnO₂:Sb), or indium tin oxide (ITO).

11. The thin-film solar module according to claim 1, wherein the photoactive semiconductor layer contains amorphous, micromorphous, or polycrystalline silicon, cadmium telluride (CdTe), organic semiconductors, gallium arsenide (GaAs), chalcopyrite- or kesterite-based semiconductors.

12. A method for producing and series connecting a thin-film solar module, comprising:
depositing a back electrode layer on a substrate, and dividing the back electrode layer by structuring lines PR,
depositing a photoactive semiconductor layer on the back electrode layer, and dividing the photoactive semiconductor layer by structuring lines PA, and
depositing a front electrode layer on the photoactive semiconductor layer, dividing the front electrode layer and the photoactive semiconductor layer into regions by structuring lines PF, and connecting the front electrode layer of a first region in series connection to the back electrode layer of a second region,
wherein the structuring lines PR are formed with bulges and edges, and the structuring lines PA are formed with bulges and edges relative to each other such that ohmic loss is reduced due to a reduced mean path distance of a current generated in the photoactive semiconductor layer through the front electrode layer.

13. A method for producing and series connecting a thin-film solar module, comprising:
depositing a front electrode layer on a transparent substrate and dividing the front electrode layer by structuring lines PF,
depositing a photoactive semiconductor layer on the front electrode layer and dividing the photoactive semiconductor layer by structuring lines PA, and
depositing a back electrode layer on the photoactive semiconductor layer, dividing the back electrode layer and the photoactive semiconductor layer into regions by structuring lines PR, and connecting in series connection the back electrode layer of a first region with the front electrode layer of a second region,
wherein the structuring lines PR are formed with bulges and edges and the structuring lines PA are formed with bulges and edges relative to each other such that ohmic loss is reduced due to a reduced mean path distance of a current generated in the photoactive semiconductor layer through the front electrode layer.

14. Use of the method according to claim 12 for producing and series connecting the thin-film solar module, wherein the thin-film solar module is made of amorphous, micromorphous, or polycrystalline silicon, cadmium telluride (CdTe), gallium arsenide (GaAs), chalcopyrite- or kesterite-based semiconductors or organic semiconductors.
